(19) United States
(12) Patent Application Publication
(10) Pub. No.: US 2012/0194249 A1
(43) Pub. Date: Aug. 2, 2012

(54) Semiconductor Integrated Circuit

(75) Inventor: Takuya Haga, Kanagawa (JP)

(73) Assignee: Kabushiki Kaisha Toshiba, Tokyo (JP)

(21) Appl. No.: 13/236,127

(22) Filed: Sep. 19, 2011

(30) Foreign Application Priority Data
Jan. 27, 2011 (JP) 2011-015376

(51) Int. Cl. H03H 11/26

(52) U.S. Cl. 327/270

(57) ABSTRACT

According to an embodiment, a semiconductor integrated circuit includes a first clock domain driven at a first frequency, a second clock domain adjacent to the first clock domain and driven at a second frequency which is different from the first frequency, a signal line provided between the first clock domain and the second clock domain, first and second DF/Fs connected to the first signal line and provided for the first clock domain and the second clock domain respectively and first and second multiplexers provided in correspondence with the first and the second DF/Fs respectively, to select one of the first frequency and the second frequency and output the selected frequency to the first and the second DF/Fs.

### CROSS-REFERENCE TO RELATED APPLICATION

This application is based upon and claims the benefit of priority from the Japanese Patent Application No. 2011-15376, filed on Jan. 27, 2011; the entire contents of which are incorporated herein by reference.

### FIELD

Embodiments described herein relate generally to a semiconductor integrated circuit.

### BACKGROUND

With an increase in scale of semiconductor integrated circuits in recent years, problems are raised about an asynchronous relationship between a plurality of clock domains. The asynchronous relationship means that there is no relation between phases of two operation clocks in two clock domains.

In the design of a semiconductor integrated circuit, a timing analysis is performed for a signal on an asynchronous boundary between two clock domains, which are asynchronous to each other. In that analysis, it is checked whether skew between bits, amount of data path delay and the like satisfy predetermined timing constraints or not.

Normally, various circuits are implemented assuming that there is no timing constraint between clock domains, a timing analysis is then performed using a static timing analysis (STA) tool, a timing report of a predetermined path is obtained and it is confirmed whether timing of the implemented circuit satisfies a predetermined timing constraint or not. Alternatively, there is also a method whereby frequencies with the same phase are set between two clock domains, the two clock domains are synchronized with each other and the timing is analyzed.

However, when such a static timing analysis (STA) tool is used, various circuits are implemented and a simulation analysis is performed on the premise that there is no timing constraint, and therefore there is a problem about timing of the asynchronous boundary that it takes a considerable time to confirm whether the designed circuit satisfies the predetermined constraint on the asynchronous boundary.

Furthermore, when clock frequencies are to be matched between two clock domains, the clock frequencies of the two clock domains need to be equalized, and therefore when there are stringent constraints in part of the circuit, there is also a problem that frequencies of the same phase cannot be set.

### BRIEF DESCRIPTION OF THE DRAWINGS

FIG. 1 is a schematic configuration diagram for illustrating a configuration of a single-chip semiconductor apparatus according to a first embodiment;

FIG. 2 is a diagram for illustrating a configuration of a control signal CS stored in a control register 11 according to the first embodiment;

FIG. 3 is a circuit diagram illustrating a circuit configuration on an asynchronous boundary ASB between two clock domains A and B according to the first embodiment;

FIG. 4 is a simplified flowchart illustrating a flow of circuit implementation according to the first embodiment;

FIG. 5 is a circuit diagram illustrating a circuit configuration on an asynchronous boundary ASB between two clock domains A and B according to a modification example of the first embodiment;

FIG. 6 is a diagram for illustrating another configuration example of the control signal CS stored in the control register 11 according to the first embodiment;

FIG. 7 is a circuit diagram illustrating a circuit configuration on an asynchronous boundary ASB between two clock domains A and B according to a second embodiment;

FIG. 8 is a diagram illustrating a signal flow during a scan path test of a clock signal CLKB according to the second embodiment; and

FIG. 9 is a circuit diagram illustrating a circuit configuration on an asynchronous boundary ASB between two clock domains A and B according to a modification example of the second embodiment.

### DETAILED DESCRIPTION

A semiconductor integrated circuit according to an embodiment is provided with a first clock domain driven at a first frequency, a second clock domain adjacent to the first clock domain and driven at a second frequency which is different from the first frequency, a first signal line provided between the first clock domain and the second clock domain, first and second latch circuits connected to the first signal line and provided for the first clock domain and the second clock domain respectively, and first and second selection sections. The first and the second selection sections are provided in correspondence with the first and the second latch circuits respectively, selects one of the first frequency and the second frequency and outputs the selected frequency to the first and the second latch circuits.

### First Embodiment

### Circuit Configuration

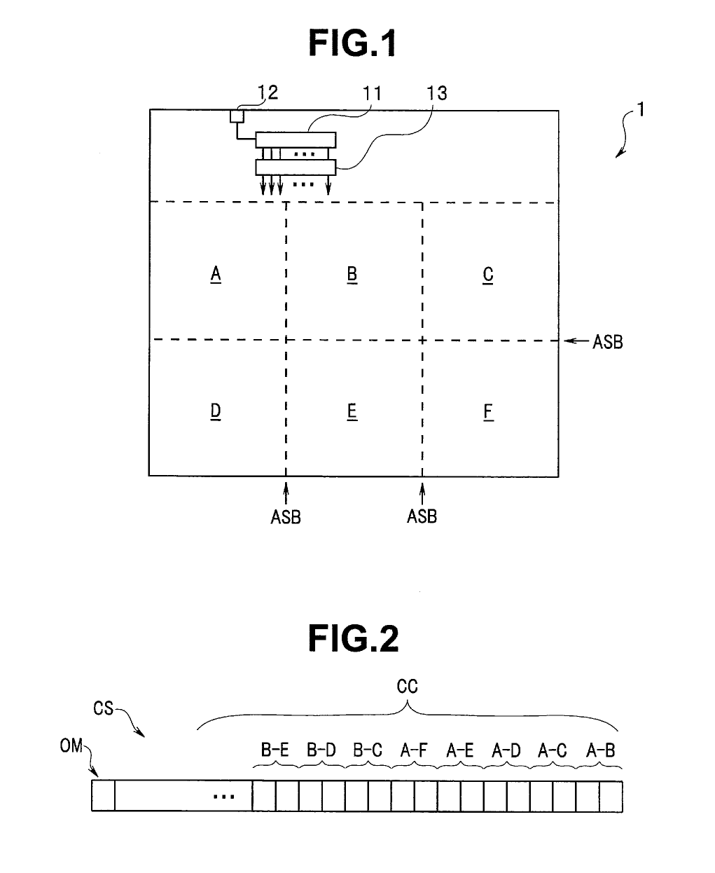

First, a configuration of a semiconductor integrated circuit according to the present embodiment will be described based on FIG. 1. FIG. 1 is a schematic configuration diagram for illustrating a configuration of a single-chip semiconductor apparatus.

A semiconductor apparatus 1 mounted with a semiconductor integrated circuit that executes various functions is configured by including a plurality of clock domains (hereinafter also simply referred to as “domain”). A plurality of domains on the substrate of the semiconductor apparatus 1 are asynchronous to each other and are driven by different clock signals. That is, the semiconductor integrated circuit of the semiconductor apparatus 1 includes a plurality of clock domains driven by clock signals of different clock frequencies. Various signals are exchanged through one or two or more data paths of signal lines provided between the domains.

According to the present embodiment, each domain is driven by a clock signal of a predetermined clock frequency, but the clock frequency may not be fixed and may vary depending on a predetermined condition. That is, although two domains have different clock frequencies, the clock frequency of the respective domains or one domain may vary depending on the condition. Signals need to be exchanged appropriately between the two domains at any varying clock frequency. Under normal circumstances, when at least one of the two domains is a domain whose clock frequency varies, signals need to be exchanged appropriately between the two domains at the fastest clock frequency.

In the present embodiment, as shown by dotted lines in FIG. 1, the semiconductor apparatus 1 has six clock domains A, B, C, D, E and F. Each domain is driven by a clock signal of a predetermined clock frequency and includes one or more circuits that realize predetermined functions. The six domains are function operation block, data bus or the like. The six domains A, B, C, D, E and F are mutually connected to all or some of the other domains via one or more signal lines.

For simplicity of explanation, FIG. 1 schematically shows the six domains in the same size. An asynchronous boundary ASB exists between two domains. On the asynchronous boundary ASB, a plurality of wiring patterns of signal lines are formed on the substrate of the semiconductor apparatus 1 to exchange signals between the two domains.

The semiconductor apparatus 1 includes a control register 11. The control register 11 is connected to a terminal 12 which is one of a plurality of terminals of the semiconductor apparatus 1 and a control signal CS can be inputted to, that is, set in the control register 11 as serial data from outside via the terminal 12. The control signal CS includes operating mode data OM and clock control data CC.

The control register 11 is a register to store the operating mode data OM and the clock control data CC. The operating mode data OM is data to specify whether the semiconductor apparatus 1 manufactured operates in a normal mode in which a predetermined function is executed or in a test mode for an operation test. The clock control data CC is data to specify a clock signal to drive each DF/F (will be described later) adjacent to the asynchronous boundary ASB.

The clock control data CC stored in the control register 11 is supplied to an output circuit 13. The output circuit 13 is a circuit for supplying each of a plurality of pieces of bit data as a clock selection signal to a corresponding multiplexer (which will be described later).

FIG. 2 is a diagram for illustrating a configuration of the control signal CS stored in the control register 11. Here, the control register 11 is a register that stores 32-bit data, but is not limited to this.

In the present embodiment, one control register 11 stores the operating mode data OM and the clock control data CC, but the operating mode data OM and the clock control data CC may be stored in respective different registers. Furthermore, in such a case, the operating mode data OM and the clock control data CC may be inputted from respective different terminals and set in their respective registers.

As shown in FIG. 2, in the present embodiment, the control signal CS includes the operating mode data OM made up of one bit and the clock control data CC made up of a plurality of bits.

The operating mode data OM is any one of “1” and “0” and here “1” represents a normal mode and “0” represents a test mode. The normal mode is a mode in which each domain operates by being driven by a predetermined clock signal so that the semiconductor apparatus 1 operates according to a predetermined specification. The test mode is a mode for driving a DF/F adjacent to the asynchronous boundary ASB by a clock signal of a clock frequency specified by the clock control data CC.

That is, when the operating mode data OM is “1” (that is, in the normal mode), a clock signal of a predetermined clock frequency is selected and supplied to each domain so that the semiconductor apparatus 1 operates according to a predetermined specification.

When the operating mode data OM is “0” (that is, in the test mode), a clock signal specified by the clock control data CC is supplied to each DF/F which is a latch circuit adjacent to each asynchronous boundary ASB in the semiconductor apparatus 1.

A register for the operating mode data OM of the control register 11 constitutes a control register that stores operating mode data for specifying any one of the normal mode which is a first operating mode in which a plurality of clock domains are driven by clock signals of different clock frequencies and the test mode which is a second operating mode in which a plurality of DF/Fs (which will be described later) which are latch circuits are driven by a clock signal selected by a multiplexer (which will be described later) which is a selection section.

The clock control data CC is made up of a plurality of pieces of bit data and each two bits are bit data for each DF/F of one corresponding asynchronous boundary ASB. In the case of FIG. 1, fifteen asynchronous boundaries ASB exist between six domains. Thus, the clock control data CC includes clock control data CC(A-B) between domains A and B, clock control data CC(A-C) between domains A and C, clock control data CC(A-D) between domains A and D, clock control data CC(A-E) between domains A and E, clock control data CC(A-F) between domains A and F, clock control data CC(B-C) between domains B and C, clock control data CC(B-D) between domains B and D, clock control data CC(B-E) between domains B and E, and so on. For example, the clock control data CC(A-B) is made up of one bit that specifies a clock signal to be supplied to one or two or more DF/Fs on the domain A side and one bit that specifies a clock signal to be supplied to one or two or more DF/Fs on the domain B side.

In the following descriptions, for simplicity of explanation, a case will be described as an example where the two domains A and B of six clock domains are taken between which signals are exchanged and the two domains are driven by clock signals CLKA and CLKB having predetermined different clock frequencies FA and FB.

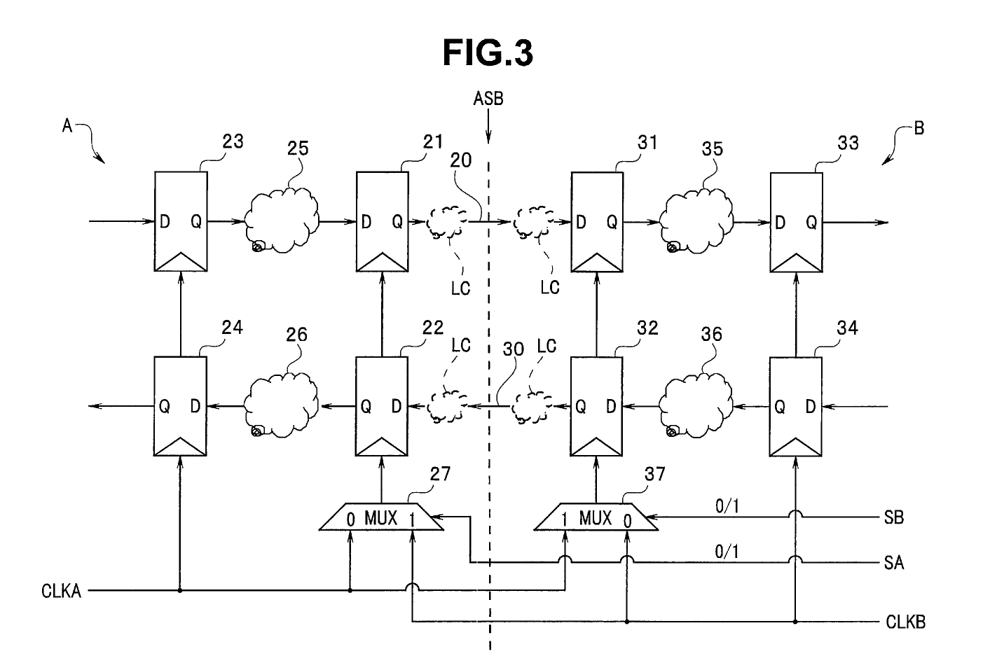

FIG. 3 is a circuit diagram illustrating a circuit configuration on the asynchronous boundary ASB between the two clock domains A and B. The domain A includes a circuit group that operates by being driven by the clock signal CLKA of the predetermined clock frequency FA. The domain B includes a circuit group that operates by being driven by the clock signal CLKB of the clock frequency FB, which is different from the clock frequency FA. The two domains A and B are connected via one or more signal lines for exchanging various signals that pass through the asynchronous boundary ASB.

FIG. 3 shows a signal line 20 for supplying a signal from the domain A to the domain B and a signal line 30 for supplying a signal from the domain B to the domain A. The domain A includes a plurality of DF/Fs 21, 22, 23 and 24 that operate based on the clock signal CLKA inputted to their respective clock input ports and each DF/F is configured to store the signal. Similarly, the domain B includes a plurality of DF/Fs 31, 32, 33 and 34 that operate based on the clock signal CLKB inputted to their respective clock input ports and each DF/F is configured to store the signal.

FIG. 3 shows only two signal lines 20 and 30 between the two domains A and B, but there can be only one signal line or more signal lines between the two domains A and B. As described above, one or two or more signal lines are provided between the two clock domains A and B between which signals are exchanged.

The DF/F 21 adjacent to the asynchronous boundary ASB is a latch circuit connected to the signal line 20 and supplies a signal to the DF/F 31 of the domain B connected to the signal line 20. The DF/F 31 adjacent to the asynchronous boundary ASB is a latch circuit connected to the signal line 20 and receives and stores a signal from the domain A.

Similarly, the DF/F 22 adjacent to the asynchronous boundary ASB is a latch circuit connected to the signal line 30 and receives and stores a signal from the DF/F 32 of the domain B connected to the signal line 30. The DF/F 32 adjacent to the asynchronous boundary ASB is a latch circuit connected to the signal line 30 and supplies a signal to the DF/F 22 of the domain A connected to the signal line 30.

That is, the domains A and B include one or two or more latch circuits connected to one or two or more signal lines respectively.

A signal stored in and outputted from the DF/F 23 is processed by various other circuits 25 and stored in the DF/F 21. A signal stored in the DF/F 22 is processed by various other circuits 26, stored in the DF/F 24 and further used for other processing in the domain A.

A signal stored in the DF/F 31 is processed by various other circuits 35, stored in the DF/F33 and further used for other processing in the domain B. A signal stored in and outputted from the DF/F 34 is processed by various other circuits 36 and stored in the DF/F 32.

In the normal mode, each circuit in the domain A is driven by the clock signal CLKA of the predetermined clock frequency FA, and therefore the clock signal CLKA is inputted to a clock input port of a latch circuit or the like and the DF/Fs 21 to 24 also latch the signal at timing of the clock signal CLKA. Similarly, in the normal mode, each circuit in the domain B is driven by the clock signal CLKB of the predetermined clock frequency FB, and therefore the clock signal CLKB is inputted to a clock input port of a latch circuit or the like and the DF/Fs 31 to 34 also latch the signal at timing of the clock signal CLKB.

The domain A includes a multiplexer (MUX) 27 as a selection section connected to the clock input ports of the DF/Fs 21 and 22 adjacent to the asynchronous boundary ASB. The multiplexer 27 receives the two clock signals CLKA and CLKB and a clock selection signal SA as input and the multiplexer 27 selects and outputs any one of the two clock signals CLKA and CLKB depending on the clock selection signal SA.

Similarly, the domain B includes a multiplexer 37 as a selection section connected to the clock input ports of the DF/Fs 31 and 32 adjacent to the asynchronous boundary ASB. The multiplexer 37 receives the two clock signals CLKA and CLKB and a clock selection signal SB as input and the multiplexer 37 selects and outputs any one of the two clock signals CLKA and CLKB depending on the clock selection signal SB.

That is, the multiplexers 27 and 37 as the selection sections are provided in correspondence with the two clock domains A and B respectively, select any one of the two clock signals CLKA and CLKB based on the clock control data CC that selects any one of the two clock signals stored in the control register 11 and supply the selected signal to each clock input port of a latch circuit.

Thus, the DF/Fs 21, 22, 31 and 32 of the asynchronous boundary ASB can be driven by any one of the two clock signals CLKA and CLKB depending on the clock selection signals SA and SB. The clock selection signals SA and SB are signals generated and outputted by the output circuit 13 based on clock control data.

In the normal mode, the operating mode data OM is “1” and the output circuit 13 is configured so as to output the clock selection signals SA and SB whereby the multiplexer 27 selects an input port (0) and the multiplexer 37 also selects an input port (0).

That is, when the normal mode is specified, the output circuit 13 is configured to supply a predetermined selection control signal to each multiplexer so that the clock signal of the predetermined clock frequency of each clock domain is selected regardless of the clock control data CC. When the test mode is specified, the output circuit 13 is configured so as to supply a selection control signal that selects a clock signal of a clock frequency specified by the clock control data CC to each multiplexer.

Therefore, after the semiconductor apparatus 1 is manufactured, it is possible to cause the semiconductor apparatus 1 to operate in any one of the normal mode and the test mode by supplying the control signal CS from outside. Furthermore, in the test mode, it is possible to cause the DF/F of the asynchronous boundary region ASB to operate at a clock frequency specified by the clock control data CC and conduct a test to determine whether various types of data are exchanged correctly between the clock domains.

Furthermore, in FIG. 3, as shown by a dotted line, there can be logic circuits LC including AND, OR circuit or the like between the DF/Fs 21 and 31, and between the DF/Fs 22 and 32.

The circuit configuration including one or more DF/Fs connected to one or more signals that pass through the asynchronous boundary ASB and two multiplexers as shown in FIG. 3 is provided for all asynchronous boundaries ASB where signals are exchanged in the semiconductor apparatus 1 shown in FIG. 1.

(Operation)

Next, operations of the circuit in FIG. 3 during implementation and testing will be described.

(During Implementation)

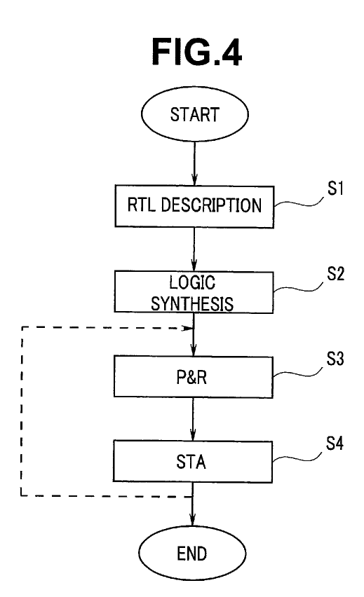

First, operation during a circuit design, that is, implementation, will be described. FIG. 4 is a simplified flowchart illustrating a flow of the circuit implementation.

Generally, a circuit design is conducted in order of program description in RTL (Register Transfer Level) language (S1), logic synthesis (S2), P&R (placement and routing) (S3) and static timing analysis (hereinafter referred to as “STA”).

In STA after P&R, since the multiplexers 27 and 37 can select and output any one of clock signals CLKA and CLKB, a timing analysis is performed on condition that the clock selection signals SA and SB for specifying clock inputs to the DF/Fs 21, 22, 31 and 32 of the aforementioned asynchronous boundary ASB are not fixed.

As a result, in the case of FIG. 3, it is possible to obtain timing analysis results for cases including the following two cases through STA. Case 1 is a case where the clock signal CLKA is inputted to the DF/Fs 21 to 24 of the domain A and the DF/Fs 31 and 32 of the domain B, and the clock signal CLKB is inputted to the DF/Fs 33 and 34 of the domain B. Case 2 is a case where the clock signal CLKA is inputted to the DF/Fs 23 and 24 of the domain A, and the clock signal CLKB is inputted to the DF/Fs 31 to 34 of the domain B and the DF/Fs 21 and 22 of the domain A.

Circuit implementation is normally performed assuming that there are no timing constraints (that is, false path) on the asynchronous boundary ASB, a timing report on a predetermined path is then obtained and it is checked whether the timing of the implemented circuit satisfies a predetermined timing constraint or not. For this reason, a considerable time has been required to check the clock timing so far.

However, as described above, by adopting a circuit configuration in which the DF/Fs adjacent to the asynchronous boundary ASB are driven so that different clock frequencies of the two domains can be selected, STA is performed for the domain A by also including the DF/Fs (e.g., DF/Fs 31 and 32) of the domain B and STA is performed for the domain B by also including the DF/Fs (e.g., DF/Fs 21 and 22) of the domain A. That is, since the timing analysis is performed using a clock frequency of one domain by also including DF/Fs of the other domain adjacent to the asynchronous boundary ASB of the one domain, it is possible to perform STA in signal lines 10 and 20 on the asynchronous boundary ASB.

Generally, when a result is obtained that satisfies a predetermined timing constraint in STA on a higher clock frequency of the two clock signals CLKA and CLKB, it is possible to judge that the timing constraint on the asynchronous boundary ASB is satisfied. When, for example, the clock frequency FB is higher than the clock frequency FA, it is possible to judge that the timing constraint on the asynchronous boundary ASB is satisfied based on the STA result in the case 2.

If it is judged that the predetermined timing constraint is not satisfied on a certain asynchronous boundary ASB, it may be possible to satisfy the predetermined timing constraint by only adjusting routing or connection route on the asynchronous boundary ASB depending on the analysis result. In FIG. 4, as shown by a dotted line, the predetermined timing constraint may be satisfied by only performing P&R (S3) over again after STA (S4).

As described above, it is possible to perform the timing analysis between the two domains A and B including the cases 1 and 2 through STA by adopting the aforementioned circuit configuration on the asynchronous boundary ASB.

(During Testing)

Operation during testing which is conducted after the semiconductor apparatus 1 is manufactured will be described.

When a circuit is designed, the semiconductor apparatus 1 is manufactured and the semiconductor apparatus 1 is tested, the testing can be conducted by inputting the control signal CS from the terminal 12 and selecting and supplying a clock signal of a desired clock frequency to each DF/F adjacent to the asynchronous boundary ASB.

For example, it is possible to write predetermined data into each domain, drive the DF/Fs 21 to 24 of the domain A and the DF/Fs 31 and 32 of the domain B by the clock signal CLKA as in the case of aforementioned case 1 and test whether the predetermined data is appropriately transmitted between the domains, and further drive the DF/Fs 31 to 34 of the domain B and DF/Fs 21 and 22 of the domain A by the clock signal CLKB as in the case of aforementioned case 2 and test whether the predetermined data is appropriately transmitted between the domains.

In this case, the clock control data CC is specified as follows. The case 1 is a case where clock control data CC(A-B) between the clock domains A and B is (0,1), the clock selection signal SA is 0 and the clock selection signal SB is 1, and in this case, the multiplexer 27 selects an input port (0) and the multiplexer 37 selects an input port (1). The case 2 is a case where clock control data CC(A-B) is (1,0), the clock selection signal SA is 1 and the clock selection signal SB is 0, and in this case, the multiplexer 27 selects an input port (1) and the multiplexer 37 selects an input port (0).

During the testing, the operating mode data OM in the control signal CS is “0” indicating the test mode. In the normal mode, the operating mode data OM is “1”, the multiplexer 27 selects an input port (0) and the multiplexer 37 also selects an input port (0).

Therefore, it is possible to conduct an AC test between the two domains in the semiconductor apparatus 1, that is, a test to check whether a signal can be appropriately transmitted between the two domains.

During testing after a semiconductor apparatus was manufactured as well, when the two clock domains were driven by clock signals of predetermined clock frequencies, it was conventionally not easy to test whether data was appropriately transmitted between the clock domains. By contrast, by adopting the aforementioned circuit configuration for the asynchronous boundary ASB, it is possible to easily test whether the data is appropriately transmitted between the clock domains.

As described above, by providing the aforementioned circuit configuration for the asynchronous boundary ASB, it is possible to easily perform the timing analysis and the AC test of the asynchronous boundary during the circuit implementation and the testing of the semiconductor apparatus.

In the aforementioned embodiment, multiplexers are provided for both of the two domains and DF/Fs adjacent to the asynchronous boundary ASB are configured to be drivable by a clock signal of each domain, but a multiplexer may be provided for only one of the two domains and DF/Fs adjacent to the asynchronous boundary ASB may be configured to be drivable by a clock signal of the other domain.

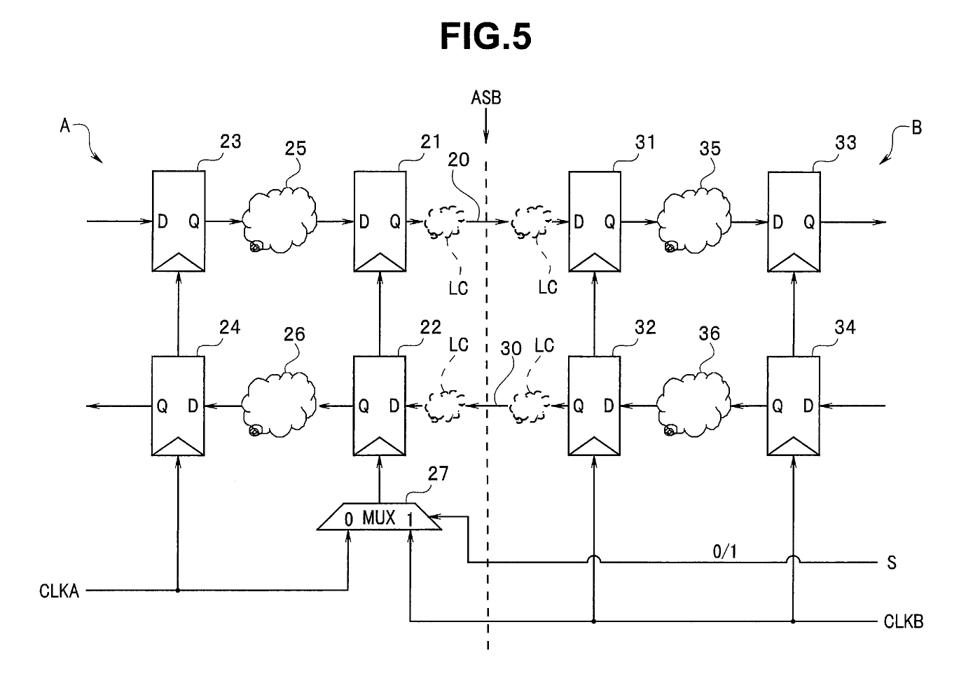

FIG. 5 is a circuit diagram illustrating a circuit configuration on the asynchronous boundary ASB between two clock domains A and B according to a modification example of the present embodiment. In FIG. 5, the same components as those in FIG. 3 will be assigned the same reference numerals and descriptions thereof will be omitted.

As shown in FIG. 5, only the multiplexer 27 is provided in the domain A and no multiplexer is provided in the domain B. The multiplexer 27 is configured to be able to select and supply the clock signal CLKB instead of the clock signal CLKA to the DF/Fs of the domain A adjacent to the asynchronous boundary ASB according to a clock selection signal S.

According to the configuration in FIG. 5, the DF/Fs 21 and 22 of the domain A are configured to be drivable by both clock signals CLKA and CLKB, and therefore during STA, it is possible to obtain a timing analysis between the two domains A and B not only when the clock signal CLKA is supplied to the DF/Fs 21 and 22 but also when the clock signal CLKB is supplied.

Furthermore, during a test, by supplying the predetermined clock selection signal S to the multiplexer 27, it is possible to supply the clock signal CLKB of the clock frequency FB to the DF/Fs 21 and 22 of the domain A and conduct an AC test between the two domains in the semiconductor apparatus 1, that is, a test to check whether a signal can be appropriately transmitted between the two domains.

FIG. 5 shows the configuration in which the clock signal CLKB is supplied to the DF/Fs 21, 22, 31 and 32 across the asynchronous boundary ASB, but a multiplexer may be provided in the domain B so as to supply the clock signal CLKA to the DF/Fs 21, 22, 31 and 32 across the asynchronous boundary ASB.

Whether the multiplexer is provided in the domain A or the domain B is determined by timing constraints of signals exchanged between the two domains.

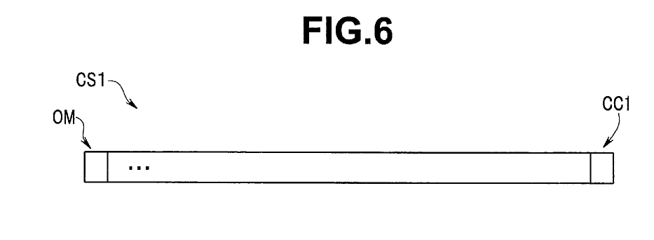

Furthermore, the control signal CS may be configured as shown in FIG. 6 instead of the configuration shown in FIG. 2. FIG. 6 is a diagram for illustrating another configuration example of the control signal CS stored in the control register 11. The control register 11 here is also a register that stores 32-bit data, but is not limited to this.

The control signal CS1 in FIG. 6 includes the operating mode data OM made up of one bit and clock control data CC1 made up of one bit. In FIG. 6, the operating mode data OM is the same as the operating mode data OM of the control signal CS in FIG. 2, but the clock control data CC1 is data that specifies by which clock signal of clock frequencies of the two clock domains each of the two DF/Fs between which the asynchronous boundary ASB is interposed operates. In the test mode, the output circuit 13 outputs a predetermined clock selection signal that specifies by which clock signal of clock frequencies of the two clock domains each of the two DF/Fs between which the asynchronous boundary ASB is interposed operates according to the value of the clock control data CC1.

For example, in the case of the circuit in FIG. 3, the output circuit 13 outputs the clock selection signal S to the DF/F adjacent to the asynchronous boundary ASB so that the multiplexers 27 and 37 select the clock signal CLKA when the value of the clock control data CC1 is “0” and select the clock signal CLKB when the value of the clock control data CC1 is “1.” Furthermore, in the case of the circuit in FIG. 5, the output circuit 13 outputs the clock selection signal S to the DF/F in the one domain adjacent to the asynchronous boundary ASB so that the multiplexer 27 selects the clock signal CLKB only when the value of the clock control data CC1 is “1.”

As described above, according to the semiconductor integrated circuits of the aforementioned embodiment and the modification example, it is possible to easily perform the timing analysis and the AC test of the asynchronous boundary.

### Second Embodiment

Next, a configuration of a semiconductor integrated circuit according to a second embodiment will be described. While the semiconductor integrated circuit of the first embodiment only includes a data path circuit, the semiconductor integrated circuit of the second embodiment includes a circuit having a scan path test function.

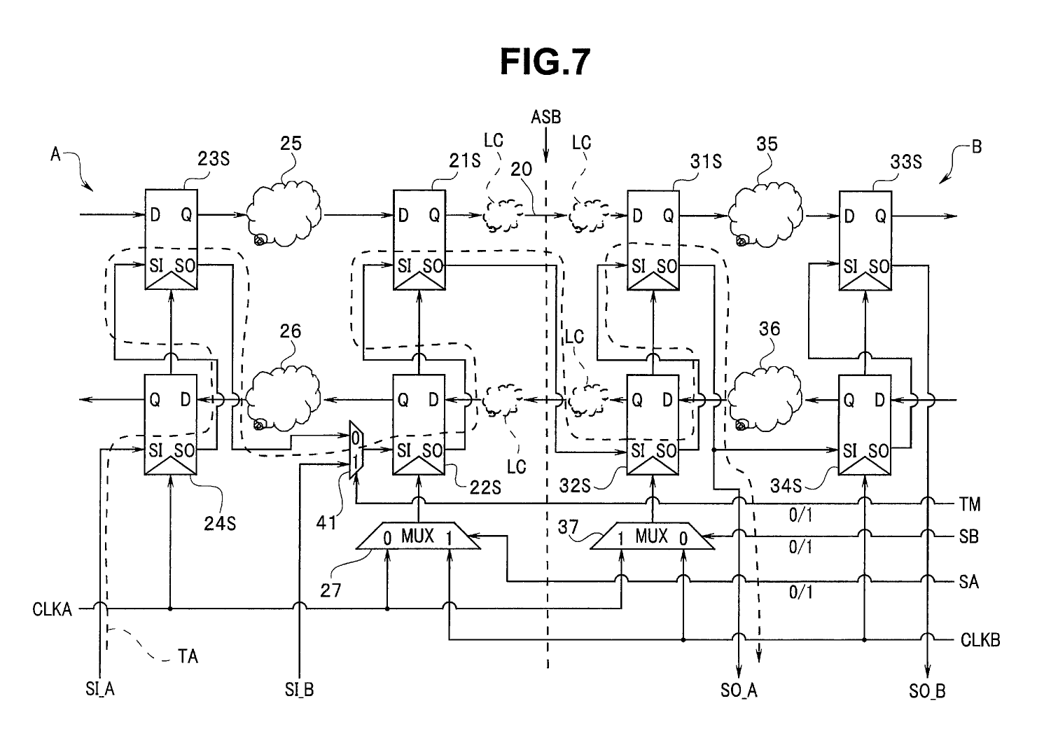

FIG. 7 is a circuit diagram illustrating a circuit configuration on an asynchronous boundary ASB between two clock domains A and B according to the second embodiment. In the present embodiment, the configuration of the semiconductor apparatus 1 is similar to that of the first embodiment shown in FIG. 1 and FIG. 2, and in FIG. 7, the same components as those in FIG. 3 will be assigned the same reference numerals and descriptions thereof will be omitted, and only components different from those in FIG. 3 will be described.

In FIG. 7, as in the case of FIG. 3, the circuit group of the domain A is driven by the clock signal CLKA of the predetermined clock frequency FA in the normal mode and the circuit group of the domain B operates by being driven by the clock signal CLKB of the clock frequency FB which is different from the clock frequency FA.

DF/Fs 21S to 24S, and 31S to 34S correspond to the DF/Fs 21 to 24, and 31 to 34 in FIG. 3 respectively and each DF/F includes a data input port SI and a data output port SO for a scan chain.

Serial input data SI_A is serial input data for a scan chain of the clock signal CLKA and serial input data SI_B is serial input data for a scan chain of the clock signal CLKB.

The serial input data SI_A is inputted to a data input port of the DF/F 24S and the serial input data SI_B is inputted to a data input port of the DF/F 22S.

The signal of a data output port of the DF/F 24S is inputted to a data input port of the DF/F 23S and a data output port of the DF/F 23S is inputted to a multiplexer 41.

The multiplexer 41 is connected to a data input port SI of the DF/F 22S. The multiplexer 41 receives the data output port SO of the DF/F 23S, the serial input data SI_B and a test mode signal TM as input, selects any one of the signal of the data output port SO of the DF/F 23S and the serial input data SI_B according to the test mode signal TM which is a test data selection signal and outputs the selected signal to the DF/F 22S.

The multiplexer 41 selects one of the two pieces of test data corresponding to the two clock signals CLKA and CLKB based on the predetermined test data selection signal and constitutes a test data selection section that supplies the selected data to one latch circuit out of one or two or more latch circuits.

The signal of the data output port of the DF/F 22S is inputted to the data input port of the DF/F 21S and the signal of the data output port of the DF/F 21S is inputted to the data input port of the DF/F 32S.

The signal of the data output port of the DF/F 32S is inputted to the data input port of the DF/F 31S, the signal of the data output port of the DF/F 31S is inputted to the data input port of the DF/F 34S and the signal of the data output port of the DF/F 34S is inputted to the data input port of the DF/F 33S.

The output of the DF/F 31S is serial output data SO_A for a scan chain of the clock signal CLKA and the output of the DF/F 33S is serial output data SO_B for a scan chain of the clock signal CLKB.

Next, operations of the circuit in FIG. 7 will be described.

During a scan path test of the clock signal CLKA, suppose both clock selection signals SA and SB are signals for selecting the clock signal CLKA so that the clock signal CLKA is inputted to the DF/Fs 21S, 22S, 31S and 32S. Suppose the test mode signal TM is “0” so that the serial input data SI_A is selected.

By supplying the serial input data SI_A to the DF/F 24S as test data, a signal passes along a scan shift path shown by a dotted line TA in FIG. 7 and the serial output data SO_A is outputted from the DF/F 31S.

When the scan path test of the clock signal CLKA is completed, it is possible to test the data path described in the first embodiment using the clock signal CLKA.

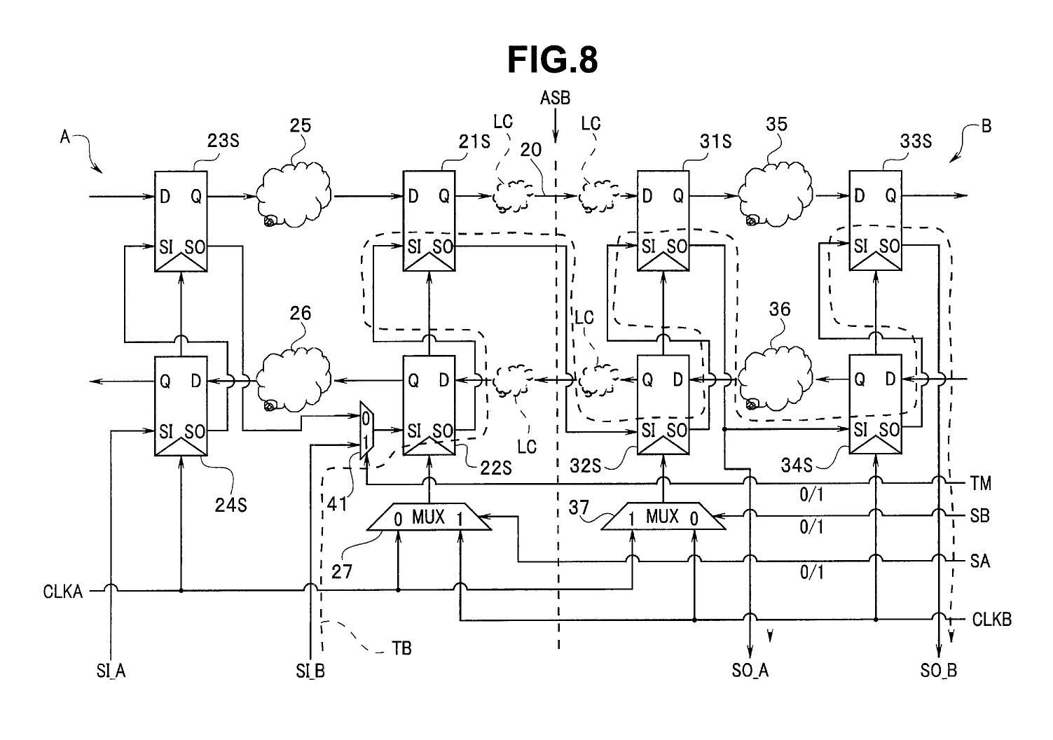

FIG. 8 is a diagram for illustrating a signal flow during a scan path test of the clock signal CLKB. During the scan path test of the clock signal CLKB, suppose both clock selection signals SA and SB are signals for selecting the clock signal CLKB so that the clock signal CLKB is inputted to the DF/Fs 21S, 22S, 31S and 32S. The test mode signal TM is set to “1” so that the serial input data SI_B is selected.

By supplying the serial input data SI_B to the DF/F 22S via the multiplexer 41 as test data, a signal passes along the scan shift path shown by a dotted line TB in FIG. 8 and the serial output data SO_B is outputted from the DF/F 33S.

When the scan path test of the clock signal CLKB is completed, it is possible to test the data path described in the first embodiment using the clock signal CLKB.

As described above, in the semiconductor apparatus 1, the multiplexer 41 as the test data selection section can perform the scan path test including a plurality of latch circuits using the test data.

Therefore, according to the present embodiment, the circuit provided with a scan path test function can also easily perform the timing analysis and the AC test of the asynchronous boundary.

Furthermore, the present embodiment may also be configured such that a multiplexer is provided for only one of the two domains and the DF/F adjacent to the asynchronous boundary ASB is drivable by a clock signal of the other domain described as one modification example (FIG. 5) of the first embodiment.

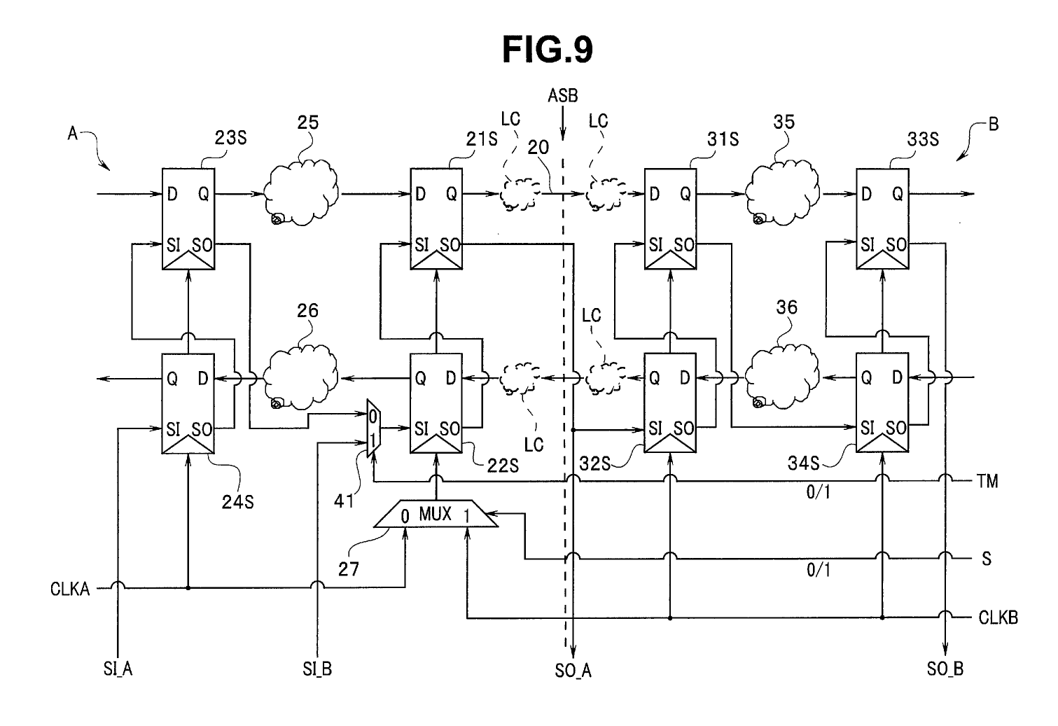

FIG. 9 is a circuit diagram illustrating a circuit configuration on the asynchronous boundary ASB between the two clock domains A and B according to a modification example of the present embodiment. In FIG. 9, the same components as those in FIG. 7 will be assigned the same reference numerals and descriptions thereof will be omitted.

The circuit configuration in FIG. 9 can also produce effects similar to those of the present embodiment described above.

Furthermore, the present embodiment may also adopt the configuration as shown in FIG. 6 described as one modification example (FIG. 6) of the first embodiment for the control signal CS.

As described so far, according to the aforementioned two embodiments and their respective modification examples, it is possible to realize the semiconductor integrated circuit that can easily perform the timing analysis and the AC test of the asynchronous boundary.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
a first clock domain configured to be driven at a first frequency;
a second clock domain adjacent to the first clock domain and configured to be driven at a second frequency which is different from the first frequency;
a first signal line provided between the first clock domain and the second clock domain;
first and second latch circuits connected to the first signal line and provided for the first clock domain and the second clock domain respectively; and
first and second selection sections provided in correspondence with the first and the second latch circuits respectively, and configured to select one of the first frequency and the second frequency and output the selected frequency to the first and the second latch circuits.

2. The semiconductor integrated circuit according to claim 1, wherein during a test operation, the first selection section outputs the first frequency to the first latch circuit and the second selection section outputs the first frequency to the second latch circuit.

3. The semiconductor integrated circuit according to claim 1, further comprising:
a second signal line provided between the first clock domain and the second clock domain;
third and fourth latch circuits connected to the second signal line and provided for the first clock domain and the second clock domain respectively; and
a test data selection section connected to an input port of the first latch circuit,
wherein the first, the second, the third and the fourth latch circuits are connected in a scan chain.

4. The semiconductor integrated circuit according to claim 1, further comprising a test data selection section configured to select one of two pieces of test data corresponding to the two clock signals of the first and the second frequencies and supply the selected test data to one of the first and the second latch circuits,
wherein a scan path test including the first and the second latch circuits can be performed based on the test data supplied from the test data selection section.

5. The semiconductor integrated circuit according to claim 4, wherein the test data selection section selects one of the two pieces of test data corresponding to the two clock signals based on a predetermined test data selection signal.

6. The semiconductor integrated circuit according to claim 1, further comprising a first control register configured to store clock control data for selecting one of the two clock signals,
wherein each of the first and the second selection sections selects one of the two clock signals based on the clock control data stored in the first control register.

7. The semiconductor integrated circuit according to claim 6, wherein the clock control data is inputted from a terminal provided for a semiconductor apparatus in which the semiconductor integrated circuit is formed and set in the first control register.

8. The semiconductor integrated circuit according to claim 6, wherein the clock control data includes bit data corresponding to the first and the second selection sections respectively.

9. The semiconductor integrated circuit according to claim 6, further comprising a second control register configured to store operating mode data for specifying one of a first operating mode in which the first and the second clock domains are driven by clock signals of different clock frequencies and a second operating mode in which the first and the second latch circuits are driven by clock signals selected by the first and the second selection sections,
wherein each of the first and the second selection sections selects one of the two clock signals based on the operating mode data stored in the second control register.

10. The semiconductor integrated circuit according to claim 9, wherein the operating mode data is inputted from a terminal provided for a semiconductor apparatus in which the semiconductor integrated circuit is formed and set in the second control register.

11. A semiconductor integrated circuit comprising:
a first clock domain configured to be driven at a first frequency;
a second clock domain adjacent to the first clock domain and configured to be driven at a second frequency which is different from the first frequency;
a first signal line provided between the first clock domain and the second clock domain;
first and second latch circuits connected to the first signal line and provided for the first clock domain and the second clock domain respectively; and
a selection section provided in correspondence with the first latch circuit and configured to select one of the first frequency and the second frequency and output the selected frequency to the first latch circuit.

12. The semiconductor integrated circuit according to claim 11, wherein during a test operation, the selection section outputs the second frequency to the first latch circuit.

13. The semiconductor integrated circuit according to claim 11, further comprising:
a second signal line provided between the first clock domain and the second clock domain;
third and fourth latch circuits connected to the second signal line and provided for the first clock domain and the second clock domain respectively; and
a test data selection section connected to an input port of the first latch circuit,
wherein the first, the second, the third and the fourth latch circuits are connected in a scan chain.

14. The semiconductor integrated circuit according to claim 11, further comprising a test data selection section configured to select one of two pieces of test data corresponding to the two clock signals of the first and the second frequencies and supply the selected test data to one of the first and the second latch circuits,
wherein a scan path test including the first and the second latch circuits can be performed based on the test data supplied from the test data selection section.

15. The semiconductor integrated circuit according to claim 14, wherein the test data selection section selects one of the two pieces of test data corresponding to the two clock signals based on a predetermined test data selection signal.

16. The semiconductor integrated circuit according to claim 11, further comprising a first control register configured to store clock control data for selecting one of the two clock signals,
wherein the selection section selects one of the two clock signals based on the clock control data stored in the first control register.

17. The semiconductor integrated circuit according to claim 16, wherein the clock control data is inputted from a terminal provided for a semiconductor apparatus in which the semiconductor integrated circuit is formed and set in the first control register.

18. The semiconductor integrated circuit according to claim 16, further comprising a second control register configured to store operating mode data for specifying one of a first operating mode in which the two clock domains are driven by clock signals of different clock frequencies and a second operating mode in which the first and the second latch circuits are driven by clock signals selected by the selection section,
wherein the selection section selects one of the two clock signals based on the operating mode data stored in the second control register.

19. The semiconductor integrated circuit according to claim 18, wherein the operating mode data is inputted from a terminal provided for a semiconductor apparatus in which the semiconductor integrated circuit is formed and set in the second control register.
